(19) United States
(12) Patent Application Publication
(10) Pub. No.: US 2008/0067897 A1
(43) Pub. Date: Mar. 20, 2008

(54) Production Method of Piezoelectric Ceramic, Production Method of Piezoelectric Element, and Piezoelectric Element

(75) Inventors: Masaru Nanao, Tokyo (JP); Takeo Tsukada, Tokyo (JP); Hideya Sakamoto, Tokyo (JP)

Correspondence Address: PEARNE & GORDON LLP, 1801 EAST 9TH STREET, SUITE 1200, CLEVELAND, OH, 44114-3108, US

(73) Assignee: TDK CORPORATION, Chuo-ku, Tokyo, JP (JP)

(21) Appl. No.: 11/573,203

(22) PCT Filed: Sep. 28, 2005
(86) PCT No.: PCT/JP05/17796

§ 371 Date: Feb. 3, 2007

(30) Foreign Application Priority Data
Sep. 30, 2004 (JP) 2004-285933

(51) Int. Cl. C04B 35/10; B29C 65/00; H01L 41/187; H01L 41/22; H01L 41/24

(52) U.S. Cl. 310/358; 156/60; 252/62.9 PZ

(57) ABSTRACT

A powder having a specific surface area of 1.8 to 11.0 m²/g was used as a powder to be sintered. Consequently, the powder has an improved sinterability, so that even by sintering at 1050° C. or lower, further at 1000° C. or lower, a piezoelectric ceramic having a high sintering density and desired piezoelectric properties can be obtained. The piezoelectric ceramic can have a main constituent represented by a composition formula (Pbₐ₁Aₐ₂)[(Z_{n1/3}Nb_{2/3})ₓTi_{y}Zr_{z}]O₃, wherein A represents at least one metal element selected from Sr, Ba and Ca, and 0.96≦a1+a2≦1.03, 0≦a2≦0.10, x+y+z=1, 0.05≦x≦0.40, 0.1≦y≦0.5 and 0.2≦z≦0.6.

### TECHNICAL FIELD

The present invention relates to a piezoelectric ceramic capable of being sintered at low temperatures, and a piezoelectric element using the same, in particular, a laminated piezoelectric element using Cu or the like for the internal electrodes of the piezoelectric element.

### BACKGROUND ART

A piezoelectric ceramic composition has a capability of freely converting electric energy into mechanical energy or vice versa and extracting the converted energy, and has been used as piezoelectric oscillators such as an actuator and a sound component or used as a sensor or the like.

For example, when a piezoelectric ceramic is used as an actuator, the piezoelectric ceramic is required to have piezoelectric properties, in particular, a large piezoelectric constant d. Generally, between the piezoelectric constant d, the electromechanical coupling coefficient k and the relative dielectric constant εr, there is a relation that d∝k(εr)^{0.5}; thus, in order to increase the piezoelectric constant d, it is necessary that the electromechanical coupling coefficient k and/or the relative dielectric constant εr be made larger.

For that purpose, for example, Patent Document 1 has proposed a piezoelectric ceramic in which the Pb in a ternary piezoelectric ceramic composed of Pb(Zn_{1/3}Nb_{2/3})O₃—PbTiO₃—PbZrO₃ is partially substituted with Ca, Sr or Ba.

Additionally, Patent Document 2 has improved the mechanical strength as well as the piezoelectric properties by further adding an additive as well as by substituting a part of the Pb with Ca or the like.

Patent Document 1: Japanese Patent Laid-Open No. 61-129888

Patent Document 2: Japanese Patent Laid-Open No. 2001-181036

However, the sintering temperatures for conventional piezoelectric ceramic compositions are as high as approximately 1100 to 1250° C., and accordingly, when laminated piezoelectric elements are prepared by using such conventional piezoelectric ceramic compositions, an expensive noble metal such as platinum (Pt) or palladium (Pd) durable to such high sintering temperatures is required to be used for internal electrodes and hence there is a problem that the production cost is high.

The reduction of the cost for the internal electrodes offers the key to the reduction of the production cost. If the sintering temperature of a piezoelectric ceramic composition can be lowered, a less expensive silver-palladium alloy (hereinafter referred to as the Ag—Pd alloy) becomes usable for internal electrodes.

Because Pd is costly, and because when the Pd content is large, Pd undergoes an oxidation-reduction reaction, and cracks and delamination are thereby caused in the laminated piezoelectric element, thus the Pd content in the Ag—Pd alloy is required to be 30% by mass or less. For the purpose of setting the Pd content at 30% by mass or less, the sintering temperature is required to be set at 1150° C. or lower and preferably 1120° C. or lower on the basis of the Ag—Pd system phase diagram. For the purpose of further reducing the production cost, the Pd content is required to be lowered, and for that purpose, the sintering temperature of the piezoelectric ceramic composition is required to be made as low as possible. In this connection, FIG. 1 shows the relation between the Pd content in the Ag—Pd alloy and the sintering temperature of the piezoelectric ceramic composition. It is to be noted that the relation between the Pd content and the sintering temperature shown in FIG. 1 is based on the Ag—Pd system phase diagram.

As shown in FIG. 1, for the purpose of setting the Pd content at 20% by mass or less, the sintering temperature is required to be set at 1050° C. or lower.

Alternatively, copper (Cu) is available as an electrode material less expensive than the Ag—Pd alloy. However, the melting point of copper is approximately 1085° C., and accordingly, the use of Cu for internal electrodes in laminated piezoelectric elements also necessitates piezoelectric ceramic compositions capable of being sintered at 1050° C. or lower.

The present invention has been achieved on the basis of the above-mentioned technical problems, and takes as its object the provision of a technique for obtaining a piezoelectric ceramic composition capable of being sintered at low-temperatures.

### DISCLOSURE OF THE INVENTION

For the purpose of improving the properties of piezoelectric ceramics, investigations have hitherto been developed by paying attention mainly on the composition. The present inventors have solved the above-mentioned problems on the basis of an approach from a process aspect such that the size of the powder before sintering as well as the composition is controlled.

Specifically, the present invention provides a production method of a piezoelectric ceramic comprising a main constituent represented by a composition formula (Pbₐ₁Aₐ₂)[(Zn_{1/3}Nb_{2/3})ₓTi_{y}Zr_{z}]O₃, characterized in that the production method comprises steps of: compacting a powder for the piezoelectric ceramic having a specific surface area of 1.8 to 11.0 m²/g; and obtaining a sintered body by sintering a resulting compacted body at 1050° C. or lower, wherein, in the composition formula: A represents at least one metal element selected from Sr, Ba and Ca; and 0.96≦a1+a2≦1.03, 0≦a2≦0.10, x+y+z=1, 0.05≦x≦0.40, 0.1≦y≦0.5 and 0.2≦z≦0.6, in terms of atomic ratio.

By using the powder having a specific surface area of 1.8 to 11.0 m²/g, as the powder to be sintered, its sinterability is improved, so that even by sintering at 1050° C. or lower, further at 1000° C. or lower, a piezoelectric ceramic having a high sintered body density and desired piezoelectric properties can be obtained.

For the purpose of improving the sinterability and the piezoelectric properties, the piezoelectric ceramic preferably comprises as an additive at least one element selected from the group consisting of Ta, Sb, Nb, W and Mo in a total content of 0.05 to 3.0% by mass, in terms of the oxides (Ta₂O₅, Sb₂O₃, Nb₂O₅, WO₃ and MoO₃), in relation to the above-mentioned main constituent.

Additionally, as the main constituent, a main constituent represented by the composition formula (Pbₐ₁Aₐ₂)[(Zn_{b/3}Nb_{2/3})ₓTi_{y}Zr_{z}]O₃ may also be employed. In this case, A represents at least one metal element selected from Sr, Ba and Ca, and it is sufficient that the following relations be satisfied: 0.96≦a1+a2≦1.03, 0≦a2≦0.10, 1<b≦3, x+y+z=1, 0.05≦x≦0.40, 0.1≦y≦0.5 and 0.2≦z≦0.6, in terms of atomic ratio.

For the purpose of obtaining a piezoelectric element by applying the present invention, it is sufficient that a laminate be obtained by alternately laminating a piezoelectric layer paste comprising the powder for the piezoelectric ceramic having a specific surface area of 1.8 to 11.0 m²/g and an internal electrode paste, and the laminate be sintered at 1050° C. or lower. For the purpose of reducing the production cost, Cu or the Ag—Pd alloy (the Pd content in the Ag—Pd alloy: 20% by mass or less) is used for the internal electrode. By using Cu less expensive than the Ag—Pd alloy for the internal electrode, the production cost can further be reduced.

It is preferable to use a piezoelectric layer paste comprising a powder having a specific surface area of 2.5 to 8.0 m²/g. The sintering temperature can be lowered down to 1000° C. or lower, and further down to 950° C. or lower.

According to the present invention, there can be obtained a piezoelectric ceramic composition capable of being sintered at 1050° C. or lower while obtaining desired piezoelectric properties. By using the piezoelectric ceramic composition, there can be obtained a laminated piezoelectric element using Cu or the like for the internal electrode.

### BRIEF DESCRIPTION OF THE DRAWINGS

FIG. 1 is a table showing the relation between the Pd content in an Ag—Pd alloy and the sintering temperature of a piezoelectric ceramic composition;

FIG. 2 is a cross-sectional view illustrating a configuration example of a piezoelectric element using the piezoelectric ceramic according to one embodiment of the present invention;

FIG. 3 is a table showing the relative dielectric constants εr and the electromechanical coupling coefficients kr of the piezoelectric ceramics prepared in Example 1;

FIG. 4 is a table showing the relative dielectric constants εr and the electromechanical coupling coefficients kr of the piezoelectric ceramics prepared in Example 2;

FIG. 5 is a table showing the displacement magnitudes of the piezoelectric elements prepared in Example 3-1; and

FIG. 6 is a table showing the displacement magnitudes of the piezoelectric elements prepared in Example 3-2.

### DESCRIPTION OF REFERENCE NUMERALS

10 . . . Laminate; 11 . . . Piezoelectric layer; 12 . . . Internal Electrode; 21, 22 . . . Terminal electrodes

### BEST MODE FOR CARRYING OUT THE INVENTION

Hereinafter, detailed description will be made on the piezoelectric ceramic and the piezoelectric element of the present invention on the basis of the embodiments.

<Chemical Composition>

The piezoelectric ceramic according to the present invention comprises a perovskite compound containing as main constituents Pb, Zr, Ti, Zn and Nb, and has a fundamental composition represented by the following formula (1) or the following formula (2). By adopting the composition represented by formula (1) or formula (2) as the main constituent, there can be obtained a piezoelectric ceramic having a high dielectric constant and a large electromechanical coupling coefficient. It is to be noted that the chemical composition as referred to herein means a composition after sintering.
(Pbₐ₁Aₐ₂)[(Zn_{1/3}Nb_{2/3})ₓTi_{y}Zr_{z}]O₃ (1)

In formula (1), A represents at least one metal element selected from Sr, Ba and Ca; and

0.96≦a1+a2≦1.03, 0≦a2≦0.10, x+y+z=1, 0.05≦x≦0.40, 0.1≦y≦0.5 and 0.2≦z≦0.6, in terms of atomic ratio.

Next, description will be made below on the reasons for imposing constraints on a1, a2, x, y and z in formula (1).

When a1+a2 exceeds 1.03, the piezoelectric properties are drastically degraded. On the other hand, when a1+a2 is less than 0.96, the dielectric constant and the electromechanical coupling coefficient become small. Thus, the range of a1+a2 is set to fall within a range of 0.96≦a1+a2≦1.03. The range of a1+a2 is preferably 0.98≦a1+a2≦1.01, and more preferably 0.99≦a1+a2≦1.005.

Then, a2 representing the substitution ratio of A to Pb is set to fall within a range of 0≦a2≦0.10. With the increase of the substitution amount of the element A, the dielectric constant is improved, but when the substitution amount becomes so large as to exceed 0.10, the sinterability is degraded. Additionally, when the substitution amount of the element A is too large, the Curie temperature is lowered, and the operating temperature as a piezoelectric ceramic is unpreferably lowered. The range of a2 is preferably 0≦a2≦0.06, more preferably 0.01≦a2≦0.06 and furthermore preferably 0.02≦a2≦0.05. Additionally, Sr is particularly preferable as the element A.

The (Zn_{1/3}Nb_{2/3}) in formula (1) serves to improve the piezoelectric properties, and the composition ratio x of the (Zn_{1/3}Nb_{2/3}) is set to fall within a range of 0.05≦x≦0.40. When x is less than 0.05, both of the dielectric constant and the electromechanical coupling coefficient are low, so that no necessary piezoelectric properties can be obtained. With the increase of x, the dielectric constant becomes high. However, since the raw material of Nb is expensive, the upper limit of x is set at 0.40. The range of x is preferably 0.05≦x≦0.30, and more preferably 0.05≦x≦0.20.

The Ti composition ratio y and the Zr composition ratio z significantly affect the dielectric constant and the electromechanical coupling coefficient, these ratios are preferably located in the vicinity of the morphotropic boundary. In view of these facts, in the present invention, the composition ratio y is set to fall within a range of 0.1≦y≦0.5 and the composition ratio z is set to fall within a rang of 0.2≦z≦0.6. The range of y is preferably 0.35≦y≦0.50 and more preferably 0.37≦y≦0.48. The range of z is preferably 0.36≦z≦0.60 and more preferably 0.38≦z≦0.50.

Pb and the element A (at least one metal element selected from Sr, Ba and Ca) each are located at the so-called A-site, and [(Zn_{1/3}Nb_{2/3})ₓTi_{y}Zr_{z}] is located at the so-called B-site. For the purpose of obtaining high piezoelectric properties, A/B is preferably set to be 0.96 or more and 1.03 or less.

In the piezoelectric element according to the present invention, the composition ratio of Zn can also be made excessive than the stoichiometric composition.
(Pbₐ₁Aₐ₂)[(Zn_{b/3}Nb_{2/3})ₓTi_{y}Zr_{z}]O₃ (2)

In formula (2), A represents at least one metal element selected from Sr, Ba and Ca; and 0.96≦a1+a2≦1.03, 0≦a2≦0.10, 1≦b≦3, x+y+z=1, 0.05≦x≦0.40, 0.1≦y≦0.5 and 0.2≦z≦0.6, in terms of atomic ratio.

The zinc and niobium, (Zn_{b/3}Nb_{2/3}), in formula (2) serve to improve the piezoelectric properties. The composition ratio of zinc b/3 is made excessive than the stoichiometric composition ratio 1/3, because the sintering temperature can thereby be made lower and the piezoelectric properties can also thereby be improved. In particular, preferably the b value set to fall within a range of 1.05 or more and 2.0 or less further improves the piezoelectric properties.

The reasons for imposing constraints on a1, a2, x, y and z are the same as in formula (1).

The piezoelectric ceramic according to the present invention contains as additives at least one element selected from the group consisting of Ta, Sb, Nb, W and Mo. By containing these elements each in a predetermined amount, there are provided such effects that the sinterability is improved, the piezoelectric properties are also improved, and further, the flexural strength is improved. Preferred among these elements is Ta because Ta has significant improvement effects on the sinterability and the piezoelectric properties.

These elements are contained in a total content of preferably 0.05 to 3.0% by mass, and more preferably 0.05 to 1.0% by mass, in terms of the oxides (Ta₂O₅, Sb₂O₃, Nb₂O₅, WO₃ and MoO₃) in relation to the main constituent, (Pbₐ₁Aₐ₂)[(Zn_{1/3}Nb_{2/3})ₓTi_{y}Zr_{z}]O₃, represented by formula (1) When the content of these oxides is less than 0.05% by mass, the above-mentioned effects cannot be enjoyed. On the other hand, when the content of these oxides exceeds 3.0% by mass, the dielectric constant, the electromechanical coupling coefficient and the sinterability are degraded.

The Ta content is preferably 0.05 to 0.80% by mass and more preferably 0.10 to 0.60% by mass in terms of Ta₂O₅.

The Sb content is preferably 0.05 to 0.80% by mass and more preferably 0.10 to 0.60% by mass in terms of Sb₂O₃.

The Nb content is preferably 0.05 to 0.80% by mass and more preferably 0.10 to 0.60% by mass in terms of Nb₂O₅.

The W content is preferably 0.05 to 0.80% by mass and more preferably 0.10 to 0.70% by mass in terms of WO₃.

The Mo content is preferably 0.05 to 0.80% by mass and more preferably 0.05 to 0.50% by mass in terms of MoO₃.

It is to be noted that the additives, Ta, Sb, Nb, W and Mo, are contained, for example, in the composition of then main constituent, and are located at the so-called B-site where Ti and Zr can be present.

Such a piezoelectric ceramic as described above can be suitably used as a material for the piezoelectric element for, for example, an actuator, a piezoelectric buzzer, a sound component or a sensor, particularly, as a material for an actuator.

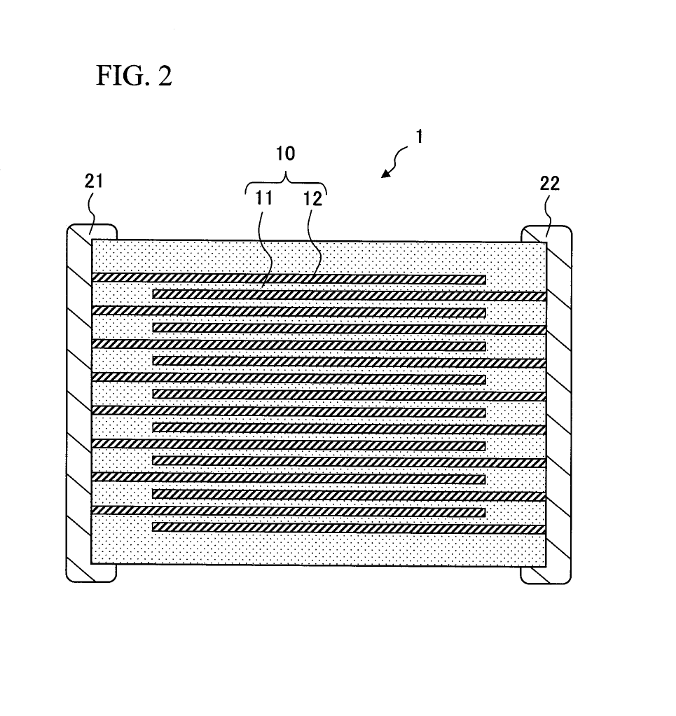

FIG. 2 shows a configuration example of a piezoelectric element using the piezoelectric ceramic according to the present embodiment. The piezoelectric element comprises a laminate 10 in which, between a plurality of piezoelectric layers 11 constituted of the piezoelectric ceramic of the present embodiment, a plurality of internal electrodes 12 are interposed. The thickness per one piezoelectric layer 11 is, for example, approximately 1 to 100 μm; both end piezoelectric layers 11 are formed to be thicker than the piezoelectric layers 11 sandwiched with the internal electrodes 12, as the case may be. The chemical composition of the piezoelectric ceramic constituting the piezoelectric layers 11 is as described above.

The internal electrode 12 can be formed of a conductive material such as Ag, Au, Cu, Pt, Pd or an alloy of these metals; however, in order to reduce the cost for the piezoelectric element, an Ag—Pd alloy (the Pd content in the Ag—Pd alloy: 20% by mass or less) or Cu is used.

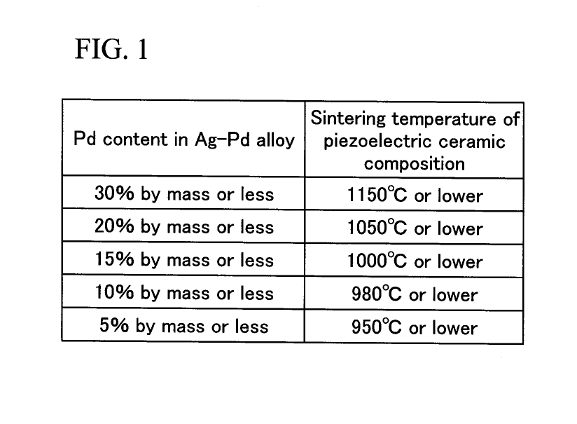

The relation between the Pd content and the sintering temperature is as shown in FIG. 1; the piezoelectric layer 11 of the present embodiment can be sintered at 1050° C. or lower, and further, at 1000° C. or lower. Consequently, the Ag—Pd alloy having a Pd content of 20% by mass or less and further an Ag—Pd alloy having a Pd content of 15% by mass or less can be used.

Because Cu is less expensive than Ag and Pd, the internal electrode 12 is preferably formed by using Cu in order to further reduce the production cost. When Cu is used, the sintering is desired to be carried out at 1050° C. or lower because the melting point of Cu is approximately 1085° C.

Now, as shown in FIG. 2, the internal electrodes 12 are alternately extended in opposite directions, and a pair of terminal electrodes 21 and 22 are disposed to be electrically connected to the alternate extension ends of the internal electrodes 12, respectively. The terminal electrodes 21 and 22 may be formed by sputtering with a metal such as gold, or alternatively, by baking a terminal electrode paste.

The terminal electrode paste contains, for example, a conductive material, a glass frit and a vehicle. The conductive material preferably comprises at least one selected from the group consisting of silver, gold, copper, nickel, palladium and platinum. Examples of the vehicle include organic vehicles and aqueous vehicles; an organic vehicle is prepared by dissolving a binder in an organic solvent, and an aqueous vehicle is prepared by including a binder, a dispersant and the like in water. The thickness of each of the terminal electrodes 21 and 22 is appropriately determined according to the intended purposes, and is usually approximately 10 to 50 μm.

<Production Method>

Next, a preferable production method of the piezoelectric element according to the present invention will be described below by following the involved steps in order.

[Raw Material Powders and Weighing Out Thereof]

As the raw materials for the main constituent, there are used powders of oxides or powders of compounds to be converted to oxides when heated. More specifically, powders of PbO, TiO₂, ZrO₂, ZnO, Nb₂O₅, SrCO₃, BaCO₃, CaCO₃ and the like can be used. The raw material powders are weighed out so that the composition represented by formula (1) may be actualized after sintering.

Then, at least one element selected from the group consisting of Ta, Sb, Nb, W and Mo is added as an additive in a predetermined content in relation to the total weight of these weighed powders. As the raw material powders for the additives, powders of Ta₂O₅, Sb₂O₃, Nb₂O₅, WO₃ and MoO₃ are prepared. It is recommended that the mean particle size of each of the raw material powders is appropriately selected within the range of 0.1 to 3.0 μm.

Incidentally, without restricting to the above described raw material powders, a powder of a composite oxide which contains two or more metals may be used as a raw material powder.

[Calcination]

The raw material powders are subjected to wet mixing and then subjected to a calcination in which the raw material powders are retained at the temperatures falling within the range from 700 to 900° C. for a predetermined period of time. This calcination is recommended to be conducted under the atmosphere of N₂ or air. The retention time in the calcination is recommended to be appropriately selected within the range from 1 to 4 hours. Incidentally, although description has been made above for the case where the raw material powders of the main constituent and the raw material powders of the additives are mixed together, and then both sets of powders are subjected to calcination, the timing for adding the raw material powders of the additives is not limited to the above described timing. Alternatively, for example, firstly the powders of the main constituent are weighed out, mixed, calcined and pulverized; then, to the main constituent mixed powder thus obtained after calcination and pulverization, the raw material powders of the additives may be added in predetermined contents to be mixed with the main constituent mixed powder.

[Pulverization]

The calcined powders are pulverized with a ball mill or a jet mill until the specific surface area becomes 1.8 to 11.0 m²/g. When the powders having a specific surface area falling within this range is used for sintering, even a sintering temperature as low as 1050° C. or lower can provide a piezoelectric ceramic that is dense and excellent in the piezoelectric properties. The specific surface area is preferably 2.5 to 8.0 m²/g and more preferably 3.5 to 8.0 m²/g. The specific surface area made to be 2.5 to 8.0 m²/g also permits a sintering at 1000° C. or lower. It is to be noted that the specific surface area in the present application is based on the nitrogen adsorption method (BET method).

For the purpose of making the specific surface area of each of the calcined powers fall within the above-mentioned range, the medium conditions may be controlled, the pulverization time may be regulated, the amount to be treated per unit time may be regulated, and the slurry concentration and others may be regulated when wet pulverization is applied.

Specifically, when the pulverization is carried out by using a ball mill, the control of the medium conditions (the increase of the amount of the media and the like) and the elongation of the pulverization time are effective. The pulverization time may be set so as for the predetermined specific surface area to be approximately obtained.

Also when the pulverization is carried out by using a jet mill, a powder having a predetermined specific surface area can also be obtained by controlling the pulverization time. The jet mill is preferably equipped with a classifier. By using the pulverizer equipped with a classifier, a powder having a targeted specific surface area can be obtained through removal of coarse powder or repulverizing the coarse powder. Alternatively, the alteration of the pulverization rate is also effective.

The step for obtaining a powder having such a small particle size that the specific surface area is 1.8 to 11.0 m²/g is not restricted to a pulverization step. It may also be designed that, for example, a powder having the above-mentioned specific surface area is obtained by subjecting the pulverized powder obtained through the pulverization step to the operations including the removal of the coarse powder or the repulverization of the coarse powder.

[Preparation of Laminate]

A vehicle is added to the calcined powder, and the mixture thus obtained is kneaded to prepare a piezoelectric ceramic paste. Then, an internal electrode paste is prepared by kneading the above-mentioned conductive material for forming the internal electrode 12 or the various oxides to be the above-mentioned conductive material after sintering, an organometallic compound or a resinate, and others with a vehicle. It is to be noted that a dispersant, a plasticizer, a dielectric material, an insulator material and others may be added to the internal electrode paste if needed.

Successively, a green chip to be a precursor for the laminate 10 is prepared by using the piezoelectric paste and the internal electrode paste, for example, by means of a printing method or a sheet method.

Thereafter, the green chip is subjected to a binder removal treatment, and is sintered to form the laminate 10. In this case, the sintering temperature is determined according to the type of the metal to be used for the internal electrode 12. As described above, when the Ag—Pd alloy (the Pd content in the Ag—Pd alloy: 20% by mass or less) or Cu is used for the internal electrode 12, the sintering temperature is set at 1050° C. or lower, and preferably set at 900 to 1000° C. The heating retention time is set at 1 to 10 hours and preferably at 2 to 8 hours.

The Ag—Pd alloy can be sintered in air. However, Cu is a base metal, and when Cu is sintered in air, Cu is oxidized to be unusable as electrode. Accordingly, when Cu is used as the internal electrode 12, the sintering is carried out in a reductive atmosphere, specifically, in a low oxygen reductive atmosphere in which the oxygen partial pressure is lower than that in the air and 1×10⁻¹² Pa or more. Even when sintered in a low oxygen reductive atmosphere, the piezoelectric layer 11 exhibits high piezoelectric properties.

When a powder having such a small particle size that the specific surface area is 1.8 to 11.0 m²/g is sintered at 1000 to 1050° C., the mean grain size of the sintered body in the piezoelectric layer 11 becomes approximately 1 to 3 μm, depending on the heating retention time. When sintered at 900 to 1000° C., the mean grain size of the sintered body becomes approximately 0.5 to 2.5 μm.

After the laminate 10 has been formed, the laminate 10 is subjected to end face polishing by means of, for example, barrel polishing or sandblast, and then the terminal electrodes 21 and 22 are formed by sputtering a metal such as gold or by printing or transfer printing a terminal electrode paste prepared in the same manner as in the internal electrode paste preparation and then baking it. Thus, the piezoelectric element shown in FIG. 2 can be obtained.

As described above, according to the present embodiment, the composition is set to be represented by formula (1), and the specific surface area of the powder before sintering is controlled to fall within the range from 1.8 to 11.0 m²/g, so that even when the sintering temperature is set at 1050° C. or lower, or further at 1000° C. or lower, the piezoelectric layer 11 can be made dense and to have high piezoelectric properties.

Therefore, the Ag—Pd alloy (the Pd content in the Ag—Pd alloy: 20% by mass or less) or Cu can be used for the internal electrode 12, and the production cost of the piezoelectric element can be reduced.

In particular, by including in the piezoelectric layer 11, in a predetermined amount, at least one selected from the group consisting of Ta, Sb, Nb, W and Mo, the sintering temperature can be made lower and the piezoelectric properties can also be more improved.

In the above descriptions, a production method of a piezoelectric element has been described by taking as an example a case where a laminated piezoelectric element is obtained. However, by applying the present invention, piezoelectric elements other than laminated piezoelectric elements can also be obtained. In this case, calcination and pulverization are carried out by following the above-mentioned procedures to obtain a powder having a specific surface area of 1.8 to 11.0 m²/g. The pulverized powder is granulated, and compressed to yield a compacted body having a desired shape. The compacted body is sintered at 1050° C. or lower, preferably at temperatures falling within a range from 900 to 1000° C. for a predetermine time to yield a sintered body. The sintered body is subjected to the polarization treatment, the polishing treatment and the formation of vibrating electrodes, and thereafter, cut to a predetermined shape to function as a piezoelectric element. The polarization treatment can be carried out by applying to the sintered body an electric field of 1.0 to 3.0 Ec (Ec: the coercive electric field) for 0.5 to 30 minutes.

By adopting the composition recommended by the present invention, and by controlling the specific surface area of the powder before sintering (the powder pulverized after calcination), even when the sintering is carried out at 1050° C. or lower, there can be obtained a piezoelectric element having, at the same time, a relative dielectric constant εr (the measurement frequency being 1 kHz) of 1800 or more and an electromechanical coupling coefficient kr (the electromechanical coupling coefficient of the radial direction vibration) of 60% or more. It is to be noted that the relative dielectric constant εr and the electromechanical coupling coefficient kr are the values measured by using an impedance analyzer (HP4194A, manufactured by Hewlett-Packard Co.). The electromechanical coupling coefficient kr has been derived on the basis of the following formula:

Electronic Materials Manufacturers Association of Japan Standard, EMAS-6100, p. 49
kr=1/(0.395*fr/(fa−fr)+0.574)^{1/2}*100

fr: Resonant frequency; fa: Anti-resonant frequency

### EXAMPLE 1

(Sample Nos. 1 to 5 and Comparative Examples 1 and 2)

As the starting materials, a PbO powder, a SrCO₃ powder, a TiO₂ powder, a ZrO₂ powder, a ZnO powder, a Nb₂O₅ powder and a Ta₂O₅ powder were prepared. These raw materials were weighed out so as to satisfy after sintering the formula, (Pb_{0.965}Sr_{0.03})[(Zn_{1/3}Nb_{2/3})_{0.1}Ti_{0.43}Zr_{0.47}]O₃, and thereafter, the Ta₂O₅ powder as an additive was added to the mixture thus obtained in a content of 0.4% by mass in relation to the total weight of the powders in the mixture. The mixture thus obtained was wet mixed for 16 hours by using a ball mill.

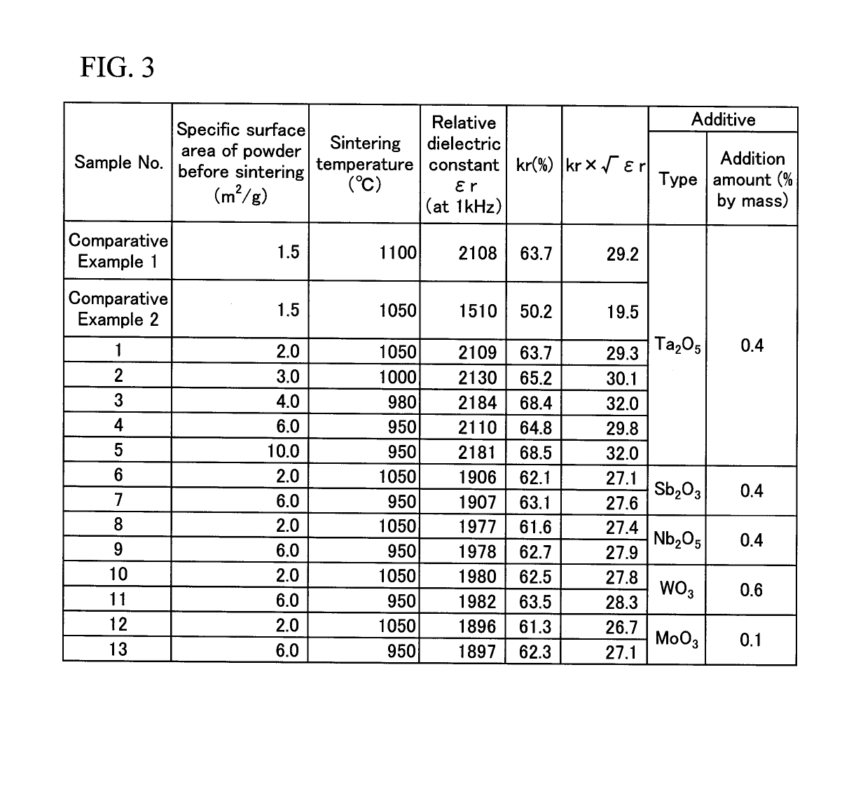

The slurry thus obtained was dried sufficiently, and thereafter, was calcined in air with retention at 700 to 900° C. for 2 hours. The calcined body was pulverized with a ball mill for 2 to 100 hours until the specific surface area shown in FIG. 3 was attained, and then the pulverized powder was dried. To the dried pulverized powder, PVA (polyvinyl alcohol) was added as a binder in an appropriate amount and granulated. The granulated powder was compacted by using a monoaxial press molding machine under a pressure of 245 MPa to yield a disc-shaped compacted body of 17 mm in diameter and 1.0 mm in thickness. The compacted body thus obtained was subjected to a binder removal treatment, and then retained in air at 950 to 1100° C. for 1 to 10 hours to yield a ceramic sample.

The ceramic sample was sliced and both surfaces of the ceramic sample were flat machined to a thickness of 0.6 mm with a lapping machine; a silver paste was printed on both surfaces of the ceramic sample, and baked thereto at 650° C.; and then the ceramic sample was subjected to a polarization treatment in a silicone oil vessel set at a temperature of 120° C. by applying an electric field of 3 kV/mm for 15 minutes.

Thus, each of the piezoelectric ceramics of Sample Nos. 1 to 5 and Comparative Examples 1 and 2 was obtained.

(Sample Nos. 6 to 13)

The piezoelectric ceramics of Sample Nos. 6 to 13 were obtained in the same manner as in Sample Nos. 1 to 5 and Comparative Examples 1 and 2 except that the types and the addition amounts of the additives were specified as shown in FIG. 3.

The piezoelectric ceramics of Sample Nos. 1 to 13 and Comparative Examples 1 and 2 were allowed to stand for 24 hours, and then subjected to the measurements of the electromechanical coupling coefficient kr of the radial direction vibration and the relative dielectric constant εr. For these measurements, an impedance analyzer (HP4194A, manufactured by Hewlett-Packard Co.) was used, and the measurement frequency of the relative dielectric constant εr was set at 1 kHz. The results thus obtained are shown in FIG. 3.

Comparative Examples 1 and 2 each were based on a powder having a specific surface area before sintering of 1.5 m²/g, and were prepared under the same conditions except for the sintering temperature. As can be seen from Comparative Examples 1 and 2, when the specific surface area of a powder before sintering is 1.5 m²/g, no sufficient densification can be attained at 1050° C., and the desired piezoelectric properties can be obtained when the sintering is carried out at a temperature (1100° C.) higher than this temperature.

On the contrary, Samples Nos. 1 to 13 for each of which the specific surface area of the powder before sintering fell within a range from 2.0 to 10.0 m²/g were sufficiently densified by sintering at 1050° C. or lower, and each were able to attain a relative dielectric constant εr (the measurement frequency being 1 kHz) of 1800 or more and an electromechanical coupling coefficient kr (the electromechanical coupling coefficient of the radial direction vibration) of 60% or more.

From the above-mentioned results, it has been verified that the technique to control the specific surface area of a powder before sintering is effective for the purpose of lowering the sintering temperature for a piezoelectric ceramic, and does not provide any adverse effect on the piezoelectric properties.

### EXAMPLE 2

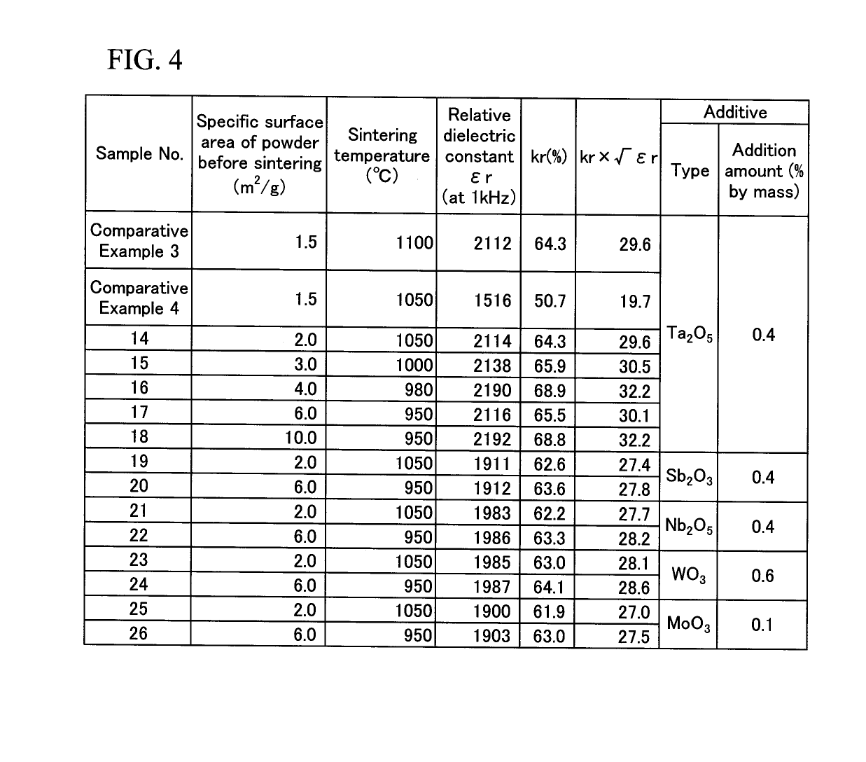

Piezoelectric ceramics were prepared in the same manner as in Example 1, except that the sintering was carried out in a low oxygen reductive atmosphere in which the oxygen partial pressure was lower than that in the air and 1×10⁻¹² Pa or more. Sample Nos. 14 to 26 thus obtained and the piezoelectric ceramics of Comparative Examples 3 and 4 were allowed to stand for 24 hours, and then subjected to the measurements of the electromechanical coupling coefficient kr of the radial direction vibration and the relative dielectric constant εr under the same conditions as in Example 1. The results thus obtained are shown in FIG. 4.

As shown in FIG. 4, also when the sintering atmosphere was changed to a low oxygen reductive atmosphere, there was verified the same tendency as in Example 1 in which the sintering was carried out in air. In other words, by setting the specific surface area of the powder before sintering to fall within the range recommended by the present invention, even such a low temperature sintering at 900 to 1050° C. was able to attain a relative dielectric constant εr (the measurement frequency: 1 kHz) of 1800 or more and an electromechanical coupling coefficient kr (the electromechanical coupling coefficient of the radial direction vibration) of 60% or more.

### EXAMPLE 3

### Example 3-1

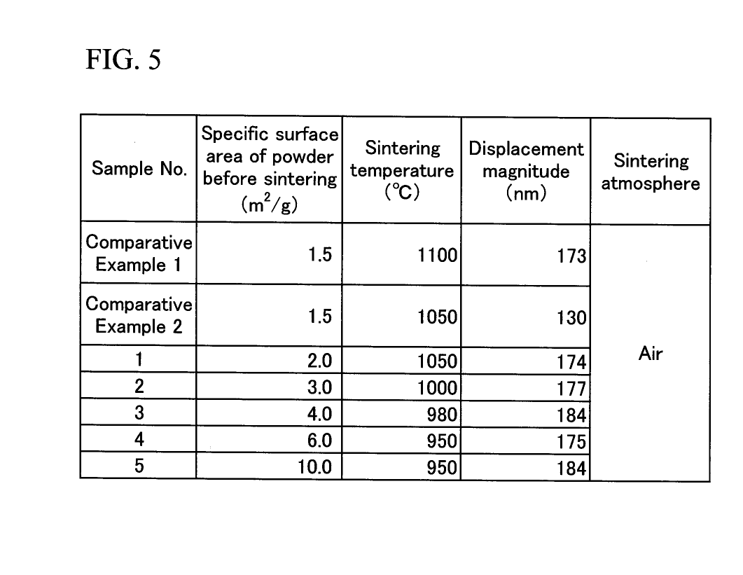

The laminated piezoelectric elements as shown in FIG. 2 were prepared by using the powders before sintering corresponding to Sample Nos. 1 to 5 of Example 1 and Comparative Examples 1 and 2. In each of the laminated piezoelectric elements, the thickness of the piezoelectric layer 11 sandwiched with the internal electrodes 12 was set at 25 μm, and the lamination number of the piezoelectric layers was set at 10; the dimension of the laminate was 4 mm long×4 mm wide; the Ag—Pd alloy (the Pd content in the Ag—Pd alloy: 20% by mass) was used for the internal electrodes 12; and the sintering was carried out in air under the sintering conditions shown in FIG. 5. The piezoelectric elements thus obtained were subjected to a displacement magnitude measurement with an applied voltage of 40 V. The results thus obtained are shown in FIG. 5.

### Example 3-2

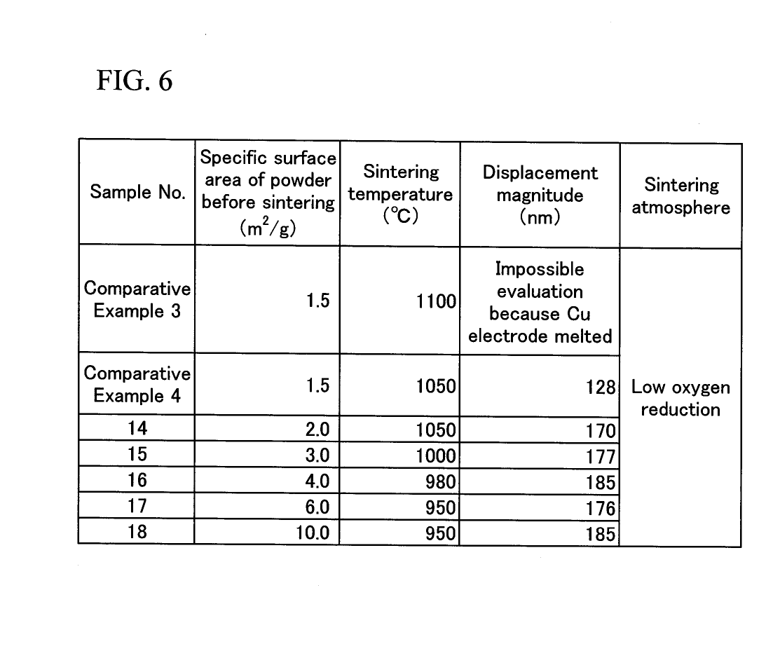

The laminated piezoelectric elements as shown in FIG. 2 were prepared by using the powders before sintering corresponding to Sample Nos. 14 to 18 of Example 2 and Comparative Examples 3 and 4. The piezoelectric elements were prepared in the same manner as in Example 3-1 except that Cu was used for the internal electrodes 12, and the sintering was carried out in a low oxygen reductive atmosphere (the oxygen partial pressure was lower than that in the air and 1×10⁻¹² Pa or more) under the conditions shown in FIG. 6. The piezoelectric elements thus obtained were subjected to a displacement magnitude measurement with an applied voltage of 40 V in the same manner as in Example 3-1. The results thus obtained are shown in FIG. 6.

As shown in FIGS. 5 and 6, those piezoelectric elements in which the specific surface area of the powder before sintering was set to fall within the range recommended by the present invention exhibited the displacement magnitudes of 170 nm or more and 180 nm or less although sintered at a temperature as low as 900 to 1050° C.

1. A production method of a piezoelectric ceramic comprising a main constituent represented by a composition formula (Pbₐ₁Aₐ₂)[(Zn_{1/3}Nb_{2/3})ₓTi_{y}Zr_{z}]O₃, characterized in that the production method comprises steps of:
compacting a powder for the piezoelectric ceramic having a specific surface area of 1.8 to 11.0 m²/g; and
obtaining a sintered body by sintering a resulting compacted body at 1050° C. or lower,
wherein, in the composition formula:
A represents at least one metal element selected from Sr, Ba and Ca; and
0.96≦a1+a2≦1.03, 0≦a2≦0.10, x+y+z=1, 0.05≦x≦0.40, 0.1≦y≦0.5 and 0.2≦z≦0.6, in terms of atomic ratio.

2. The production method of a piezoelectric ceramic according to claim 1, characterized in that the compacted body is sintered at 1000° C. or lower.

3. The production method of a piezoelectric ceramic according to claim 1, characterized in that the piezoelectric ceramic comprises as an additive at least one element selected from the group consisting of Ta, Sb, Nb, W and Mo in a total content of 0.05 to 3.0% by mass, in terms of Ta₂O₅, Sb₂O₃, Nb₂O₅, WO₃ and MoO₃, respectively, in relation to the main constituent.

4. The production method of a piezoelectric ceramic according to claim 1, characterized by compacting a powder for the piezoelectric ceramic having a specific surface area of 2.5 to 8.0 m²/g.

5. A production method of a piezoelectric element comprising:
a piezoelectric layer constituted of a piezoelectric ceramic comprising a main constituent represented by a composition formula (Pbₐ₁Aₐ₂)[(Zn_{1/3}Nb_{2/3})ₓTi_{y}Zr_{z}]O₃,; and
an internal electrode constituted of an Ag—Pd alloy having a Pd content of 20% by mass or less or of Cu;
characterized in that the production method comprises steps of:
obtaining a laminate by alternately laminating a piezoelectric layer paste comprising a powder for the piezoelectric ceramic having a specific surface area of 1.8 to 11.0 m²/g and an internal electrode paste; and
sintering the laminate at 1050° C. or lower,
wherein, in the composition formula:
A represents at least one metal element selected from Sr, Ba and Ca; and
0.96≦a1+a2≦1.03, 0≦a2≦0.10, x+y+z=1, 0.05≦x≦0.40, 0.1≦y≦0.5 and 0.2≦z≦0.6, in terms of atomic ratio.

6. The production method of a piezoelectric element according to claim 1, characterized in that the piezoelectric layer paste comprises a powder having a specific surface area of 2.5 to 8.0 m²/g.

7. A piezoelectric element comprising a plurality of piezoelectric layers and a plurality of internal electrodes interposed between the plurality of piezoelectric layers, characterized in that:
the piezoelectric layers are constituted of a piezoelectric ceramic comprising a main constituent represented by a composition formula (Pbₐ₁Aₐ₂)[(Zn_{1/3}Nb_{2/3})ₓTi_{y}Zr_{z}]O₃; and
the internal electrodes are constituted of an Ag—Pd alloy having a Pd content of 20% by mass or less or with Cu,
wherein, in the composition formula:
A represents at least one metal element selected from Sr, Ba and Ca; and
0.96≦a1+a2≦1.03, 0≦a2≦0.10, x+y+z=1, 0.05≦x≦0.40, 0.1≦y≦0.5 and 0.2≦z≦0.6, in terms of atomic ratio.

8. The piezoelectric element according to claim 7, characterized in that the internal electrodes are constituted of Cu.

9. The piezoelectric element according to claim 7, characterized in that the internal electrodes are constituted of the Ag—Pd alloy having a Pd content of 20% by mass or less.

10. The piezoelectric element according to claim 7, characterized in that 0.01≦a2≦0.06.

11. The piezoelectric element according to claim 7, characterized in that 0.02≦a2≦0.05.

12. The piezoelectric element according to claim 7, characterized in that 0.35≦y≦0.50.

13. The piezoelectric element according to claim 7, characterized in that 0.36≦z≦0.60.

14. The piezoelectric element according to claim 7, comprising Sr as the A.

15. The piezoelectric element according to claim 7, characterized by comprising as an additive at least one element selected from the group consisting of Ta, Sb, Nb, W and Mo in a total content of 0.05 to 3.0% by mass, in terms of Ta₂O₅, Sb₂O₃, Nb₂O₅, WO₃ and MoO₃, respectively, in relation to the main constituent.

16. The piezoelectric element according to claim 15, characterized by comprising Ta as an additive in a content of 0.05 to 0.80% by mass in terms of Ta₂O₅ in relation to the main constituent.

17. The piezoelectric element according to claim 7, characterized by having a relative dielectric constant εr of 1800 or more at 1 kHz.

18. The piezoelectric element according to claim 7, characterized by having an electromechanical coupling coefficient kr of 60% or more.

19. A production method of a piezoelectric ceramic comprising a main constituent represented by a composition formula (Pbₐ₁Aₐ₂)[(Zn_{b/3}Nb_{2/3})ₓTi_{y}Zr_{z}]O₃, characterized in that the production method comprises steps of:
compacting a powder for the piezoelectric ceramic having a specific surface area of 1.8 to 11.0 m²/g; and
obtaining a sintered body by sintering a resulting compacted body at 1050° C. or lower,
wherein, in the composition formula:
A represents at least one metal element selected from Sr, Ba and Ca; and
0.96≦a1+a2≦1.03, 0≦a2≦0.10, 1≦b≦3, x+y+z=1, 0.05≦x≦0.40, 0.1≦y≦0.5 and 0.2≦z≦0.6, in terms of atomic ratio.

20. The production method of a piezoelectric ceramic according to claim 19, characterized in that 1.05≦b≦2.00.

21. The production method of a piezoelectric ceramic according to claim 2, characterized in that the piezoelectric ceramic comprises as an additive at least one element selected from the group consisting of Ta, Sb, Nb, W and Mo in a total content of 0.05 to 3.0% by mass, in terms of Ta₂O₅, Sb₂O₃, Nb₂O₅, WO₃ and MoO₃, respectively, in relation to the main constituent.
